(19) United States
(12) Patent Application Publication
(10) Pub. No.: US 2025/0357726 A1
(43) Pub. Date: Nov. 20, 2025

(54) DUAL-WAVELENGTH REFERENCE SEMICONDUCTOR LASER SOURCE

(71) Applicant: Keysight Technologies, Inc., Santa Rosa, CA (US)

(72) Inventors: Valentina Moskalenko, Campbell, CA (US); Ryan Scott, Woodland, CA (US)

(21) Appl. No.: 18/665,864

(22) Filed: May 16, 2024

(51) Int. Cl. H01S 5/10; H01S 5/00; H01S 5/068; H01S 5/0687

(52) U.S. Cl. CPC H01S 5/1096; H01S 5/0014; H01S 5/0085; H01S 5/06808; H01S 5/0687

(57) ABSTRACT

An apparatus for providing two wavelengths (λ and λ+Δλ) from a laser that are locked to the same resonance. The apparatus includes an optical resonator connected to the optical coupler and adapted to attenuate the third optical signal at a characteristic wavelength. The apparatus also includes a feedback control circuit configured to change properties of the laser to be locked until an error signal indicative of the difference between the characteristic wavelength and the wavelength of the laser is offset by approximately Δλ/2. The apparatus may be a photonic integrated circuit (PIC), and may have the feedback control circuit off-chip.

### BACKGROUND

Lasers are used in a variety of applications. In many such applications, providing a comparatively highly accurate output wavelength or frequency signal from the laser is useful.

In certain applications mentioned above, a frequency stabilized Helium-Neon (HeNe) laser is used. However, HeNe lasers usually have only a 3-year lifetime after which the laser must be replaced. Replacing the HeNe laser in certain applications such as integrated lithography systems used in, for example, the semiconductor industry may be costly or impractical due to their restricted accessibility within the system and the incurred downtime.

Furthermore, so-called precision HeNe laser emits in the visible wavelength band, which is outside of the telecommunications (telecom) and data communications (datacom) spectra and thereby limit their integration into instruments (e.g., wavemeters) used in telecom and datacom applications. Moreover, many stabilized HeNe lasers are being discontinued, with no viable solutions commercially available.

Semiconductor lasers may be implemented in various applications, including telecom and datacom. The output of semiconductor lasers is often stabilized using gases having resonance frequencies/wavelengths in the telecom and datacom band. However, these lasers only emit a single mode (whereas for displacement measurement, a dual wavelength stabilized laser source is needed) and often require a dither signal (i.e., modulation) for stabilization. Moreover, these lasers may not provide sufficiently accurate output signals.

What is needed, therefore, is a center-lock wavelength stabilized semiconductor laser that is comparatively inexpensive and overcomes the shortcomings of known lasers such as discussed above.

### BRIEF DESCRIPTION OF THE DRAWINGS

The representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified schematic diagram of a laser source, and an apparatus for locking a center-wavelength of the laser, in accordance with a representative embodiment.

FIG. 2A is a graph showing a transmission spectrum of resonance of apparatus for locking a center-wavelength of a laser source in accordance with a representative embodiment.

FIG. 2B is a graph showing a transmission spectrum of resonance of an apparatus useful in adjusting a bias point of a laser source in accordance with a representative embodiment.

FIG. 3 is a graph showing balanced photocurrent as a function of laser frequency for different shift frequencies for locking a center-wavelength of a laser source in accordance with a representative embodiment.

FIG. 4 is a perspective view of a photonic integrated circuit used to lock a center-wavelength of a laser, in accordance with a representative embodiment.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only and is not intended to be limiting. The defined terms are in addition to the technical and scientific meanings of the defined terms as commonly understood and accepted in the technical field of the present teachings.

Unless otherwise noted, when a first element (e.g., an optical waveguide) is said to be connected to a second element (e.g., another optical waveguide), this encompasses cases where one or more intermediate elements or intervening devices may be employed to connect the two elements to each other. However, when a first element is said to be directly connected to a second element, this encompasses only cases where the two elements are connected to each other without any intermediate or intervening devices. Similarly, when a signal is said to be coupled to an element, this encompasses cases where one or more intermediate elements may be employed to couple the signal to the element. However, when a signal is said to be directly coupled to an element, this encompasses only cases where the signal is directly coupled to the element without any intermediate or intervening devices.

As used in the specification and appended claims, the terms “a”, “an” and “the” include both singular and plural referents, unless the context clearly dictates otherwise. Thus, for example, “a device” includes one device and plural devices. As used in the specification and appended claims, and in addition to their ordinary meanings, the terms “substantial” or “substantially” mean to within acceptable limits or degree. In certain representative embodiments, substantially means within 10% of a target value. As used in the specification and the appended claims and in addition to its ordinary meaning, the term “approximately” means to within an acceptable limit or amount to one having ordinary skill in the art. For example, “approximately the same” means that one of ordinary skill in the art would consider the items being compared to be the same. In certain representative embodiments, approximately means within 10% of a target value.

Relative terms, such as “above,” “below,” “top,” “bottom,” may be used to describe the various elements” relationships to one another, as illustrated in the accompanying drawings. These relative terms are intended to encompass different orientations of the elements thereof in addition to the orientation depicted in the drawings. For example, if an apparatus (e.g., a photonic IC) depicted in a drawing were inverted with respect to the view in the drawings, an element described as “above” another element, for example, would now be “below” that element. Similarly, if the apparatus were rotated by 90° with respect to the view in the drawings, an element described “above” or “below” another element would now be “adjacent” to the other element; where “adjacent” means either abutting the other element, or having one or more layers, materials, structures, etc., between the elements.

By the present teachings certain improvements to the technical fields of optical communications and other applications of lasers are realized. As will become apparent to one of ordinary skill in the art the present teachings are adapted to provide a dual-wavelength stabilized laser source, which generates two optical modes at different wavelengths (λ and λ+Δλ), in mutually orthogonal polarization states. Beneficially, these two modes are stabilized using an optical resonance. In certain representative embodiments, the optical resonance is realized using an absorptive optical resonator. For example, the absorptive optical resonator may comprise a gas cell to provide atomic or molecular resonances. In other representative embodiments, a high-Q optical ring resonator that is coupled to an optical waveguide may be used. In such an embodiment, the transmission spectrum of the ring resonator can be used like an absorptive gas resonance. Notably, and as described more fully below, in certain representative embodiments, the apparatus is realized in a photonic integrated circuit (PIC). In such embodiments, use of a gas cell or similar absorptive optical resonator may be difficult to implement. As such, the present teachings contemplate the use of optical waveguide ring resonators to provide the high-Q optical ring resonance.

As will become clear as the present description continues, in accordance with certain representative embodiments, the apparatuses enabling the laser modes to be locked on molecular or atomic resonances, thereby a comparative high absolute accuracy and precision from the apparatus. Just by way of illustration, by the present teachings, a 1550 nm wavelength (193.4 THz) laser can be locked with a accuracy and precision of <0.04 pm (≤5 MHz). When a high-Q resonator is implemented in an apparatus of a representative embodiment, comparatively high precision (e.g., <5 MHz) can be also be realized.

Among other applications, the stabilized lasers of the various representative embodiments are contemplated for use in measurement of displacement and velocity, as well as in applications in which a single wavelength reference laser is realized after filtering one of the output modes.

One illustrative application of the apparatuses of representative embodiments in which two orthogonally polarized optical modes are needed include heterodyne Doppler shift measurements. In such applications, one mode is transmitted to a moving target, reflected and then the polarization is rotated to match the second laser mode and mixed with the second laser mode. By measuring the beat note between these modes, the Doppler shift, and therefore velocity and displacement can be calculated. This application requires high coherence between the modes and accurately known wavelength of the modes. Since the beat frequency is not 0 Hz, the sign of the velocity change and therefore the direction of the motion of the target movement can be determined. As will be appreciated, the direction of motion cannot be determined using homodyne detection. Just by way of illustration, velocity calculated from the Doppler shift may be used in position and displacement sensors, which require comparatively high resolution and accuracy. For example, precision measurement of position and displacement is beneficial in semiconductor industry instruments for wafer manufacturing and quality control.

Another application of the apparatuses of representative embodiments includes calibration of spectral analysis instruments (e.g., optical wavemeter). To achieve comparatively high accuracy of a wavemeter, a stable reference signal with a known wavelength is needed. Optical wavemeters are typically based on optical free-space or integrated interferometers. However, with time, the optical delay length between the interferometer arms may vary with environmental conditions or with material stresses in the case of an integrated solution. This leads to change in spectral response of such wavemeters and therefore degradation of spectral accuracy. In this case, a single reference laser signal with high precision and accuracy is beneficial. As described more fully below, the apparatuses of the present teachings are adapted to adjust applied laser current to account for laser drift due to various conditions such as device temperature or aging. By the apparatuses of various representative embodiments, such drift is compensated by calibration using a feedback circuit described below. These adjustments can be performed either actively, or the wavemeter spectral response may be monitored using the reference signal from the laser of the apparatus.

Various embodiments of an apparatus for locking a wavelength of a laser are disclosed below. In one representative embodiment, the apparatus comprises: an optical splitter configured to receive an optical signal and to split an input optical signal to provide a first optical signal and a second optical signal; an optical modulator disposed in a first arm of the apparatus and adapted to cause a wavelength shift (Δλ) in the first optical signal; a polarization rotator connected to an output of the optical modulator and adapted to rotate the polarization of the first optical signal so that it is orthogonal to the incident first optical signal; an optical coupler configured to receive an output optical signal from the first arm, and the second optical signal from a second arm of the apparatus and to provide a third optical signal and an output optical signal; an optical resonator connected to the optical coupler and adapted to attenuate the third optical signal at a characteristic wavelength; a polarization beamsplitter connected to an output of the optical resonator and adapted to direct light of the output of the optical resonator having a first polarization state to a first photodetector adapted to provide a first photocurrent, and direct light of the output of the optical resonator having a second polarization state to a second photodetector adapted to provide a second photocurrent, wherein a difference between the first and second photocurrents from the first and second photodetectors increase when a difference between the characteristic wavelength and the laser wavelength increases, or decrease when the difference between the characteristic wavelength decrease; and an electronic feedback control circuit configured to change properties of the laser to be locked until an error signal indicative of the difference between the characteristic wavelength and the wavelength of the laser is offset by approximately Δλ/2.

In accordance with another representative embodiment, a photonic integrated circuit (PIC) for locking a wavelength of a laser is described. The PIC comprises: a substrate; an optical splitter disposed over the substrate and configured to receive an optical signal and to split an input optical signal to provide a first optical signal and a second optical signal; an optical modulator disposed over the substrate and disposed in a first arm of the PIC and adapted to cause a wavelength shift (Δλ) in the first optical signal; a polarization rotator disposed over the substrate and connected to an output of the optical modulator and adapted to rotate the polarization of the first optical signal so that it is orthogonal relative to the incident first optical signal (e.g., a 90° rotation for linear polarization); an optical coupler disposed over the substrate and configured to receive an output optical signal from the first arm, and the second optical signal from a second arm of the PIC and to provide a third optical signal and an output optical signal; an optical resonator disposed over the substrate and connected to the optical coupler and adapted to attenuate the third optical signal at a characteristic wavelength; a polarization beamsplitter disposed over the substrate and connected to an output of the optical resonator and adapted to direct light of the output of the optical resonator having a first polarization state to a first photodetector adapted to provide a first photocurrent, and direct light of the output of the optical resonator having a second polarization state to a second photodetector adapted to provide a second photocurrent, wherein a difference between photocurrents from the first and second photodetectors increase when a difference between the characteristic wavelength and the mean wavelength of the first and second optical signal increases, or decrease when the difference between the characteristic wavelength and mean wavelength of the first and second optical signal decrease; and an electronic feedback control circuit configured to change properties of the laser to be locked until an error signal indicative of the difference between the characteristic wavelength and the wavelength of the laser is offset by approximately ±Δλ/2.

Notably, in the description of the various representative embodiments, the optical signals are alternately described in terms of their wavelength (2) and/or in terms of their frequency (f), where the speed (v) is given by λf. Accordingly, the wavelength of a signal described in terms of its frequency and the frequency of a signal can readily be determined as needed.

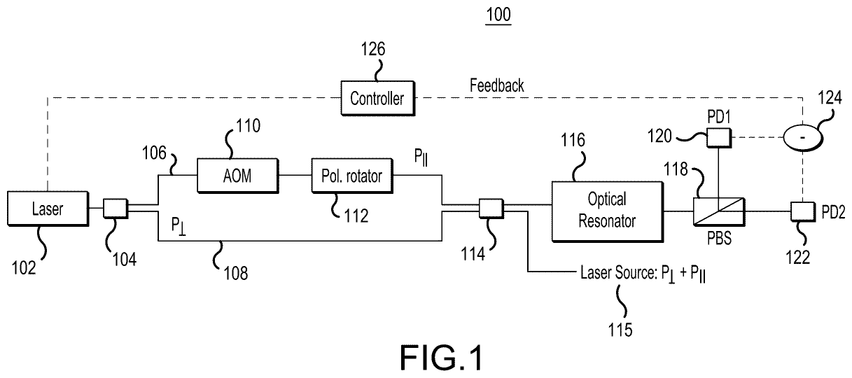

FIG. 1 is a schematic diagram of a laser 102, and an apparatus 100 for locking a center-wavelength of the laser 102, in accordance with a representative embodiment. As will be appreciated, the optical signals transmitted in the apparatus 100 may be transmitted using optical waveguides (e.g., optical fiber) selected for their transmission characteristics (e.g., single and multimode waveguides). Moreover, the various optical components of the apparatus may be optical waveguide-based devices, or may be discrete element devices. All such waveguides and devices are within the purview of one of ordinary skill in the art and may not be explicitly described to avoid obscuring the salient aspects of the representative embodiments.

The laser 102 is illustratively a semiconductor laser, such as a distributed feedback (DFB) laser. As alluded to above, the laser 102 is susceptible to drift due to a variety of sources, such as operating and ambient temperature.

The laser 102 may be used for a variety of applications, such as metrology or optical communications, where maintaining the center-wavelength within a comparatively precise wavelength range is useful if not essential to proper operation of an apparatus in which the laser 102 is deployed. Generally, reference lasers in various applications are specified to have an absolute stability of approximately 0.1 ppm. The present teachings are designed to afford such stability in the laser 102.

The laser 102 provides an output signal that is incident on an optical splitter 104, which is a 50:50 splitter, and outputs a first optical signal to a first arm 106 of the apparatus and a second optical signal to a second arm 108 of the apparatus. Notably, the output from the laser is in a particular polarization state, and as such, the polarization state of first and second optical signals at the output of the optical splitter 104 is the same.

The first optical signal is incident on an optical modulator 110. In accordance with a representative embodiment, the optical modulator 110 comprises an acousto-optic optical modulator (AOM) that is adapted to cause the frequency (and thus the wavelength) of the first optical signal to shift by a finite amount (λf). It is noted that while the AOM is merely an illustrative optical modulator 110, such a device does is beneficial at least because its output provides a frequency shift without appreciable (if any) additional spectral frequency components.

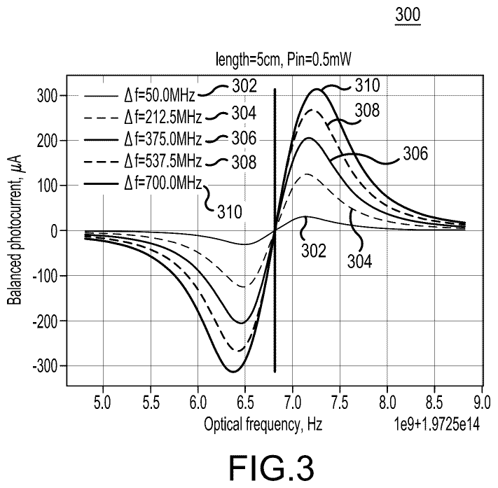

Notably, the shift provided by the optical modulator 110 is an appreciable fraction of the optical resonance width that will be interrogated. For typical gas or molecular resonances of interest, the desired frequency shift is tens to hundreds of MHz, which is in the range of typical AOM's. The highest error signal slope is typically achieved when the frequency shift is approximately equal to the full-width half maximum width of the resonance. See FIG. 3. As is known, the AOM comprises a piezoelectric material transducer on an optical material that causes a shift in the frequency of the first optical signal so at its output, the frequency is f+λf. Of course, therefore, the wavelength of the first optical signal is λ+Δλ. By contrast, the frequency and wavelength of the second arm 108 are unchanged. Notably, the use of the AOM for the optical modulator 110 is merely illustrative, and other optical modulators are contemplated to provide the frequency shift λf needed to adjust the output frequency of the laser 102 to provide the desired output frequency/wavelength of the laser via the feedback/control circuit described below. As described more fully below, the frequency shift λf provides a baseline difference between the power levels of the two orthogonal polarization states of the first and second optical signals after propagating through the optical resonator. As will be appreciated, when these power levels shift along the transmission spectrum of the optical resonator (but maintain their difference), error signals are used by the feedback/control circuit to adjust the bias to the laser 102 to adjust the output wavelength of the laser 102 to its desired value.

Alternative optical modulators are contemplated. Generally, the optical modulator 110 is a known device adapted to thermo-optically, stress-optically, electro-optically or magneto-optically change of the effective index of the medium to realize the desired frequency shift used to control the output signal from the laser 102 using via the feedback/control circuit of various representative embodiments. More generally, optical devices adapted to provide a time-varying phase shift to realize the desired shift in the frequency/wavelength of the first optical signal in the first arm 106 are contemplated for use in accordance with various representative embodiments.

The output of the optical modulator 110 is provided to a polarization rotator 112. In accordance with a representative embodiment, the polarization rotator may be a known polarizer such as a commercially available half wave plate. More generally, the polarization rotator 112 is a known device adapted to rotate the polarization axis of the first optical signal by π/2. A variety of known devices, such as a birefringent element, a Faraday rotator and a total internal reflection (TIF) rotator are contemplated.

The polarization rotator 112 rotates the polarization of the polarized light from the laser by π/2, and as a result the polarization state of the first optical signal is rotated π/2 relative to the first optical signal. In accordance with a representative embodiment, the optical signal at the output of the laser 102 (and thus the second optical signal in the second arm 108) may be transverse electric (TE) mode light. After traversing the polarization rotator 112, the first optical signal emerges as transverse magnetic (TM) mode light, and is orthogonal to the TE mode of the second optical signal in the second arm 108. Accordingly, the second optical signal at the output of the polarization rotator 112 has a frequency (or wavelength) that is shifted by λf (or Δλ) and has a polarization state that is orthogonal to the polarization state of the first optical signal.

The first and second optical signals are provided to a polarization combiner 114. The polarization combiner 114 is known device comprising, for example, a polarization beamsplitter operating in reverse.

In accordance with a representative embodiment, the polarization combiner may also comprise an optical splitter (e.g., a 2:2 optical splitter). The polarization combiner is adapted to combine the first and second optical signals so that their two orthogonal polarization states are provided to an optical resonator 116. Moreover, after emerging from the 2:2 splitter, a portion of the input signals provided to the polarization combiner is provided as an output signal 115 comprising both orthogonal polarization states. As alluded to above, and among other uses, the output signal could ultimately be used in heterodyne applications such as a wavemeter or velocity/displacement apparatus.

The combined output optical signal from the polarization combiner 114 is incident on an optical resonator 116. The optical resonator 116 is an absorptive optical resonator adapted to have an absorption line at a characteristic wavelength. The optical resonator is selected to absorb light having a wavelength that is substantially the same wavelength as the desired output wavelength of the laser 102. Notably, in accordance with the present teachings, at center lock, the output wavelength from laser 102 will be equal to the wavelength of a selected absorption line of the reference gas plus/minus half of the wavelength shift (+Δλ/2) provided by the optical modulator.

In certain representative embodiments, the optical resonator 116 comprises an atomic or molecular material that has an absorption line in the region of interest, to thereby foster adjusting the output of the laser 102 that line using a feedback/control circuit described more fully below. In certain representative embodiments, the atomic or molecular material comprises a gas. In other representative embodiments, such as described below, the optical resonator 116 may comprise an optical waveguide ring resonator. Regardless of the type of optical resonator 116 selected, the optical resonator is adapted to provide an absorption line at the desired output wavelength of the laser 102, and does not significantly change (e.g., when the temperature or pressure of the absorption gas is changing). As such, the accuracy of the absorption of the reference gas provides a accuracy in the lock of laser 102 that is approximately 0.1 ppm or less.

In order to generate a usable error signal, the wavelength of the laser 102 to be locked to the absorption line needs to be on the order of 102 MHz from 3 dB point of the absorption line selected for locking the wavelength of the laser 102. Otherwise, the error signal might become too small to have a substantial effect at the integrator of the control loop (discussed below). This however is not difficult to achieve as the wavelength of the laser 102 can easily be tuned such that it is close enough to the characteristic wavelength of the gas of the optical resonator.

The apparatus 100 further comprises a polarization beam splitter (PBS) 118 adapted to receive the output signal from the optical resonator 116. The PBS 118 reflects light of one polarization state and transmits light of the other polarization state, which is orthogonal to the first polarization state.

The apparatus 100 further comprises a first photodetector 120 adapted to receive the light reflected from the PBS 118 and a second photodetector 122 adapted to receive light transmitted through the PBS 118 as shown. The first photodetector 120 is configured to detect the optical signal of the first polarization state and to provide a corresponding first photocurrent PD1. The second photodetector 122 is configured to detect the optical signal of the second polarization state and to provide a corresponding first photocurrent PD2.

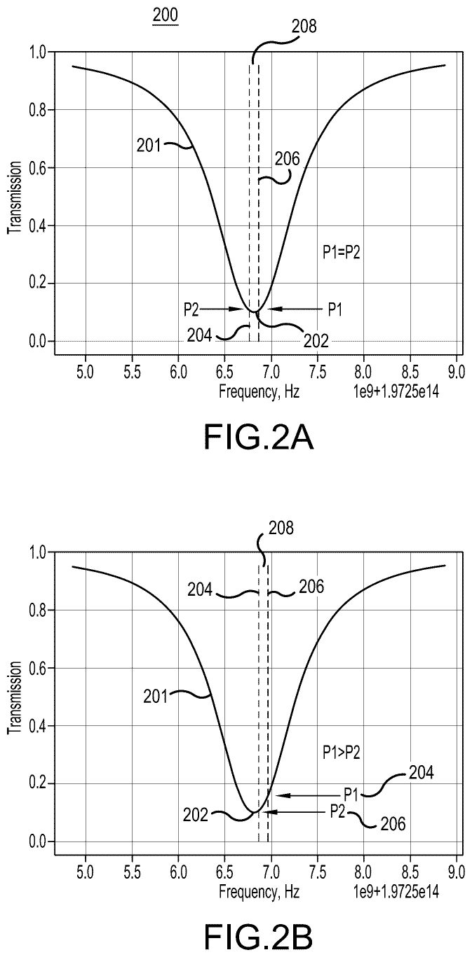

The first and second photocurrents PD1 and PD2 are input to an adder 124. The adder 124 is configured to determine a difference between the first photocurrent P1 and the second photocurrent P2. Notably, when the mean value between the wavelength of the first and second optical signals is at the center of the resonance the difference in photocurrents PD1 and PD2 is zero. When the laser wavelengths changes, so does the wavelength of the frequency shifted signal. In this case the difference in the PD1 and PD2 is no longer zero. As described more fully in connection with FIG. 2B, when these power levels shift along the transmission spectrum of the optical resonator (but maintain their absolute difference (i.e., ΔP is constant), error signals are used by the feedback/control circuit to adjust the bias to the laser 102 to adjust the output wavelength of the laser 102 to its desired value.

The output from the adder 124 provides an (electrical) error signal E indicating the difference. Notably, the absorption of the optical resonator 116 is substantially the same for both states of polarization. As such, when P1=P2 the wavelength of the laser 102 is at the absorption maximum of the optical resonator 116 (±Δλ/2). As alluded to above, the absorption maximum is selected to coincide with the desired wavelength. By contrast, and as described more fully below, when the output wavelength of the laser 102 drifts, P1 and P2 do not have the same magnitude, and the shift in P1 and P2 does not equal remain constant. In this instance, the error signal ε is positive or negative and is indicative to the shift in the two orthogonal polarization states on the transmission spectrum of the optical resonator 116. The feedback/control loop is used to adjust the bias to the laser 102 until ε=0 at which point the laser 102 provides an output signal at the wavelength of maximum absorption plus (minus) Δλ/2.

The output of the adder 124 is provided to a feedback control circuit 126 that is configured to provide a control signal in response to the error signal E. That is, the feedback control circuit 126 outputs the control signal based, at least in part, on each of the first photocurrent P1 and the second photocurrent P2, and comparison thereof. The control signal controls the bias of the laser 102 enabling the automatic tuning of the laser 102 to the desired output wavelength, which is substantially equal to the characteristic wavelength of the reference gas plus (minus) Δλ/2, and is occurs again when the error signal ε=0 (but ΔP 208 (see below) is constant). Beneficially, by adjusting the bias point with the control signal, the laser 102 is controlled to tune its output to be substantially equal to the characteristic wavelength of the reference gas plus (minus) Δλ/2.

In an embodiment, the feedback control circuit 126 is a Proportional Integral (PI) controller configured to receive and process the error signal ε indicating the difference between the wavelength of the output signal of the laser 101 and the characteristic wavelength, and to output the control signal CS in response. The PI controller includes an amplifier (not shown) that receives and amplifies the error signal E, outputting amplified error signal. The PI controller further includes an integrating logic device (not shown) that performs an integration function on the amplified error signal over time to provide an integrated error signal, and an adder (not shown) that adds the amplified error signal and the integrated error signal to output the control signal used to adjust the laser. In an embodiment, the PI controller may be replaced by a PID controller that also includes differentiating logic. Of course, the feedback control circuit 126 may include other types of control circuits, such as an on-off controller or controllers using fuzzy logic, without departing from the scope of the present teachings.

FIG. 2A is a graph 200 showing a transmission spectrum of resonance of apparatus for locking a center-wavelength of a laser in accordance with a representative embodiment. Various aspects and details of the presently described representative embodiments are common to those described above in connection with the representative embodiments of FIG. 1. These common aspects and features may not be repeated to avoid obscuring the presently described representative embodiments.

The graph 200 of the transmission versus frequency illustrates the absorption of the medium used in the optical resonator 116 of the apparatus 100. As noted above, in certain embodiments the medium comprises an atomic or molecular absorption medium. In other representative embodiments a high-Q resonator (e.g., a ring resonator) may be used, and as noted below is beneficial to implementation of the apparatus in a PIC.

The resonance peak 202 (absorption peak) of curve 201 shows the maximum absorption of the medium at resonance. In the described representative embodiment, an absorption peak 202 is selected to substantially match the desired output wavelength of the laser 102.

Line 204 shows spectral position of the first optical signal and line 206 shows spectral position of the second optical signal. The corresponding optical power levels which reach photodetectors are P1 and P2 respectively. As noted above, the laser 102 outputs optical frequencies near the resonant frequency of the gas (or ring resonator), and the first and second optical signals from the two orthogonal polarizations states will experience different attenuation depending on the laser wavelength. Lines 204 and 206 intersect the transmission/absorption curve at frequency/transmission levels indicative of the absorption of the first and second orthogonal optical signals output from the optical resonator.

A difference 208 between the transmission between the first and second optical signals is shown. Accordingly, the difference 208 between these lines 204 and 206 is frequency shift λf from the optical modulator 110. In the presently described representative embodiment it can be seen that P1 is equal to P2. As shown, the first and second optical signals from the two orthogonal polarizations states intersect the transmission curve at frequencies to be substantially symmetric with respect to the resonance peak 202 and are separated by the frequency shift λf from the optical modulator 110. In this case, the output of the laser 102 and the shifted signal are symmetrically positioned in respect to the resonance peak 202 and no adjustments of the bias to the laser 102 is required.

FIG. 2B is the graph 200 showing a transmission spectrum of resonance of apparatus for locking a center-wavelength of a laser in accordance with a representative embodiment. Various aspects and details of the presently described representative embodiments are common to those described above in connection with the representative embodiments of FIG. 1. These common aspects and features may not be repeated to avoid obscuring the presently described representative embodiments.

The graph 200 of the transmission versus frequency illustrates the absorption of the medium used in the optical resonator 116 of the apparatus 100. As noted above, in certain embodiments the medium comprises an atomic or molecular absorption medium. In other representative embodiments a high-Q resonator (e.g., a ring resonator) may be used, and as noted below is beneficial to implementation of the apparatus in a PIC.

The resonance peak 202 shows the maximum absorption of the medium at resonance. In the described representative embodiment, an absorption peak 202 is selected to substantially match the desired output wavelength of the laser 102.

Line 204 shows spectral position of the first optical signal and line 206 shows spectral position of the second optical signal. The corresponding optical power levels which reach photodetectors are P1 and P2, respectively, As noted above, and the first and second optical signals from the two orthogonal polarizations states will experience different attenuation depending on the laser wavelength. Lines 204 and 206 intersect the transmission/absorption curve at frequency/transmission levels indicative of the absorption of the first and second orthogonal optical signals output from the optical resonator.

A difference 208 shows the different attenuation between the first and second optical signals. Accordingly, the difference 208 between first and second optical signals is proportional to the frequency shift λf from the optical modulator 110 and to the displacement of the lines 204 and 206 from the peak. In the presently described representative embodiment it can be seen that P1>P2. As shown, the first optical signal intersects the transmission curve at a frequency that is greater than the frequency at which the second optical signal intersects the transmission curve. As such, while the difference 208 caused by the frequency shift λf from the optical modulator 110 remains the same, the points of intersection of the two orthogonal optical signals are not symmetric above the resonance peak 202. In this case, the bias to the laser 102 adjustments must be adjusted until the points of intersection are substantially symmetric about the resonance peak 202.

FIG. 3 is a graph 300 showing balanced photocurrent (PD1-PD2)_as a function of laser frequency for different shift frequencies 302˜310 for locking a center-wavelength of a laser in accordance with a representative embodiment. The solid line at frequency 310 indicates the optical frequency at which first and the second optical signals are positioned substantially symmetrically in respect to the peak. When the lines are shifted towards lower frequency in respect to the peak the balanced photocurrent is negative. When the lines are shifted towards higher frequency in respect to the peak the balanced photocurrent is positive. This way the balanced photocurrent dependency is linear and goes to zero when the optimal wavelength (when the lines are symmetrically positioned in respect to the peak) is achieved. The balanced signal is then used as an error signal which is optimized by the feedback electronics to reach 0. Graph 300 shows the balanced photocurrent as a function of laser frequency for different shift frequencies, λf, assuming 0.5 mW laser output power and 5-cm long acetylene gas cell at 50 Torr pressure. As expected, when λf approaches the full width at half maximum (FWHM) of the resonance (˜ 700 MHz), the error signal has its steepest dependency on the optical frequency variation.

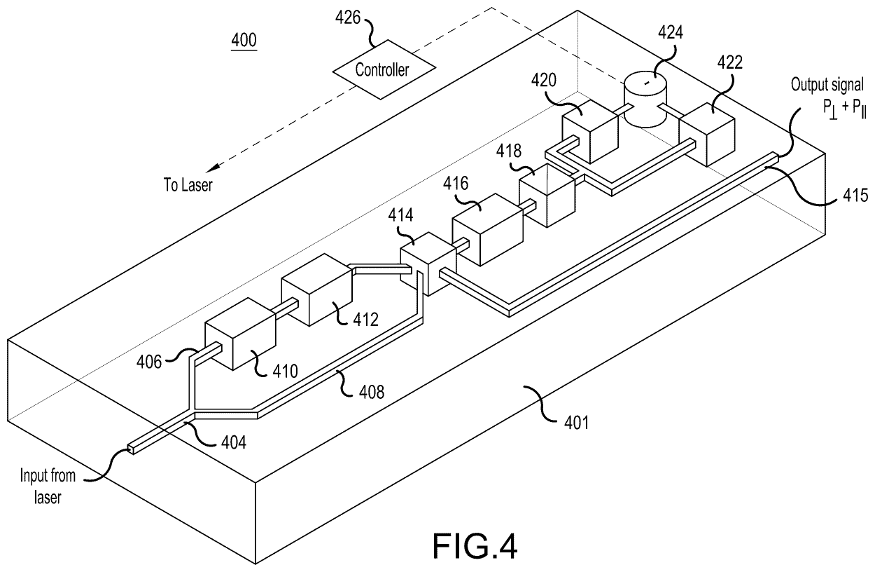

FIG. 4 is a perspective view of a part of a photonic integrated circuit (PIC) 400 used to lock a wavelength of a laser, in accordance with a representative embodiment. Notably, many aspects of the various components of the apparatus 100 described above in connection with FIGS. 1-3 are common to those of PIC 400 described presently. These details may not be repeated in the interest of brevity and clarity.

Referring to FIG. 4, the PIC 400 comprises a series of connected optical waveguides. In accordance with a representative embodiment, the optical waveguides of the PIC 400 are waveguides which consist of a channel (core) made of a material having a higher index of refraction disposed in/surrounded by a material (cladding) having a lower index of refraction than the channel. In accordance with a representative embodiment, the waveguides of the PIC 400 may comprise a core, which is illustratively silicon, disposed in a cladding of silicon dioxide, which may be disposed on a silicon substrate. Generally, PIC 400 of various embodiments may be implemented in any material system in which a waveguide and ideally a frequency shifter can be built. For example, the core disposed in the cladding for the slab waveguide can be silicon (Si) in silicon dioxide (SiO₂), silicon nitride (Si₃N₄) in silicon dioxide (SiO₂), or doped indium phosphide (InP) in undoped indium phosphide, although other material systems may be incorporated without departing from the scope of the present teachings. Further details of the various elements, materials and fabrication techniques may be found in commonly-owned U.S. Pat. No. 11,522,340 to Nebendahl. The entire disclosure of U.S. Pat. No. 11,522,340 is specifically incorporated herein by reference.

Input from a laser (e.g., laser) is provided at a first end of the PIC 400. The laser is coupled to an input waveguide by a known optical coupling method. For some material systems (notably InP) the laser may be integrated in the same photonic IC.

The laser is illustratively a semiconductor laser, such as a distributed feedback (DFB) laser. As alluded to above, the laser is susceptible to drift due to a variety of sources, such as operating and ambient temperature.

The laser may be used for a variety of applications, such as metrology or optical communications, where maintaining the center-wavelength within a comparatively precise wavelength range is useful if not essential to proper operation of an apparatus in which the laser is deployed. Generally, reference lasers in various applications are specified to have an absolute stability of approximately 0.1 ppm. The present teachings are designed to afford such stability in the laser.

The laser provides an output signal that is incident on an optical splitter 404, which is a 50:50 splitter, and outputs a first optical signal to a first arm 406 of the apparatus and a second optical signal to a second arm 408 of the apparatus. Notably, the output from the laser is in a particular polarization state, and as such, the polarization state of first and second optical signals at the output of the optical splitter 404 is the same.

The first optical signal is incident on an optical modulator 410. In accordance with a representative embodiment, the optical modulator 410 comprises an acousto-optic optical modulator (AOM) that is adapted to cause the frequency (and thus the wavelength) of the first optical signal to shift by a finite amount (λf). The required shift is between tens and hundreds of MHz, which is in the range of typical AOM possibilities. Highest signal-to-noise-ratio is achieved when the shift is around half width of the half maximum of the resonance. As is known, the AOM comprises a piezoelectric material that causes a shift in the frequency of the first optical signal so at its output, the frequency is f+λf. Of course, therefore, the wavelength of the first optical signal is λ+Δλ. By contrast, the frequency and wavelength of the second arm 408 are unchanged. Notably, the use of the AOM for the optical modulator 410 is merely illustrative, and other optical modulators are contemplated to provide the frequency shift λf needed to adjust the output frequency of the laser (not shown in FIG. 4) to provide the desired output frequency/wavelength of the laser via the feedback/control circuit described below. As described more fully below, the frequency shift λf provides a baseline difference between the power levels of the two orthogonal polarization states of the first and second optical signals. As will be appreciated, when these power levels shift along the transmission spectrum of the optical resonator (but maintain their absolute difference), error signals are used by the feedback/control circuit to adjust the bias to the laser to adjust the output wavelength of the laser to its desired value.

Alternative optical modulators are contemplated. Generally, the optical modulator 410 is a known device adapted to thermo-optically, stress-optically, electro-optically or magneto-optically change of the effective index of the medium to realize the desired frequency shift used to control the output signal from the laser using via the feedback/control circuit of various representative embodiments. More generally, optical devices adapted to provide a phase shift to realize the desired shift in the frequency/wavelength of the first optical signal in the first arm 406 are contemplated for use in accordance with various representative embodiments.

The output of the optical modulator 410 is provided to a polarization rotator 412. In accordance with a representative embodiment, the polarization rotator may be a known polarizer such as a commercially available half wave plate. More generally, the polarization rotator 412 is a known device adapted to rotate the polarization axis of the first optical signal by π/2. A variety of known devices, such as a birefringent element, a Farraday rotator and a total internal reflection (TIF) rotator are contemplated.

The polarization rotator 412 rotates the polarization of the polarized light from the laser by π/2, and as a result the polarization state of the first optical signal is rotated π/2 relative to the first optical signal. In accordance with a representative embodiment, the optical signal at the output of the laser (and thus the second optical signal in the second arm 408) may be transverse electric (TE) mode light. After traversing the polarization rotator 412, the first optical signal emerges as transverse magnetic (TM) mode light, and is orthogonal to the TE mode of the second optical signal in the second arm 408. Accordingly, the second optical signal at the output of the polarization rotator 412 has a frequency (or wavelength) that is shifted by λf (or Δλ) and has a polarization state that is orthogonal to the polarization state of the first optical signal.

The first and second optical signals are provided to a polarization combiner 414. The polarization combiner 414 is known device comprising, for example, a polarization beamsplitter operating in reverse.

In accordance with a representative embodiment, the polarization combiner may also comprise an optical splitter (e.g., a 2:2 optical splitter). The polarization combiner is adapted to combine the first and second optical signals so that their two orthogonal polarization states are provided to an optical resonator 416. Moreover, after emerging from the 2:2 splitter, a portion of the input signals provided to the polarization combiner is provided as an output signal 415 comprising both orthogonal polarization states. As alluded to above, and among other uses, the output signal could ultimately be used in heterodyne applications such as a wavemeter or velocity/displacement apparatus.

The combined output optical signal from the polarization combiner 414 is incident on an optical resonator 416. The optical resonator 416 is an absorptive optical resonator adapted to have an absorption line at a characteristic wavelength or eigenmode. The optical resonator is selected absorb light having a wavelength that is substantially the same wavelength as the desired output wavelength of the laser. Notably, in accordance with the present teachings, at center lock, the output wavelength from laser will be equal to the wavelength of a selected absorption line of the reference gas.

In certain representative embodiments, the optical resonator 416 comprises an atomic or molecular material that has an absorption line in the region of interest, to thereby foster adjusting the output of the laser that line using a feedback/control circuit described more fully below. In certain representative embodiments, the atomic or molecular material comprises a gas. In other representative embodiments, such as described below, the optical resonator 416 may comprise an optical waveguide ring resonator. Notably, hermetic sealing of the gas on a PIC is challenging, and may require custom processing. As such, rather than providing an atomic or molecular material for the optical resonator 416, the optical resonator 416 may comprise an optical waveguide ring resonator fabricated during the processing to provide the PIC 400.

Regardless of the type of optical resonator 416 selected, the optical resonator is adapted to provide an absorption line at the desired output wavelength of the laser, and does not significantly change (e.g., when the temperature or pressure of the absorption gas is changing). As such, the accuracy of the absorption of the reference gas provides an accuracy in the lock of laser that is approximately 0.1 ppm or less.

The PIC 400 further comprises a polarization beam splitter (PBS) 418 adapted to receive the output signal from the optical resonator 416. The PBS 418 reflects light of one polarization state and transmits light of the other polarization state, which is orthogonal to the first polarization state.

The PIC 400 further comprises a first photodetector 520 adapted to receive the light reflected from the PBS 418 and a second photodetector 522 adapted to receive light transmitted through the PBS 418 as shown. The first photodetector 520 is configured to detect the optical signal of the first polarization state and to provide a corresponding first photocurrent PD1. The second photodetector 522 is configured to detect the optical signal of the second polarization state and to provide a corresponding first photocurrent PD2.

The first and second photocurrents PD1 and PD2 are input to an adder 424. The adder 424 is configured to determine a difference between the first photocurrent P1 and the second photocurrent P2. As will be appreciated, the connections from the first and second photodetectors are electrical connections.

Notably, when the mean value between the wavelength of the first and second optical signals is at the center of the resonance the difference in photocurrents PD1 and PD2 is zero. When the laser wavelengths changes, so does the wavelength of the frequency shifted signal. In this case the difference in the PD1and PD2 is no longer zero. As described more fully above in connection with FIG. 2B, when these power levels shift along the transmission spectrum of the optical resonator (but maintain their absolute difference (i.e., ΔP is constant), error signals are used by the feedback/control circuit to adjust the bias to the laser to adjust the output wavelength of the laser 102 to its desired value.

The output from the adder 424 provides an error signal ε indicating the difference. Notably, the absorption of the optical resonator 416 is substantially the same for both states of polarization. As such, when P1=P2 the wavelength of the laser 102 is at the absorption maximum of the optical resonator 416 (+Δλ/2). As alluded to above, the absorption maximum is selected to coincide with the desired wavelength. By contrast, and as described more fully below, when the output wavelength of the laser 102 drifts, P1 and P2 do not have the same magnitude, and the shift in P1 and P2 does not equal remain constant. In this instance, the error signal ε is positive or negative and is indicative to the shift in the two orthogonal polarization states on the transmission spectrum of the optical resonator 416. The feedback/control loop is used to adjust the bias to the laser 102 until ε=0 at which point the laser 102 provides an output signal at the wavelength of maximum absorption plus (minus) Δλ/2.

The output of the adder 424 is provided to a feedback control circuit 426 that is configured to provide a control signal in response to the error signal E. That is, the feedback control circuit 426 outputs the control signal based, at least in part, on each of the first photocurrent P1 and the second photocurrent P2, and comparison thereof.

Notably, while the feedback control circuit 426 may be a component of the PIC 400 and disposed thereon, the feedback control circuit 426 may be disposed elsewhere (e.g., an integrated circuit board (not shown) connected to the PIC 400 and connected to the adder 424. Such electrical connections are shown as dashed lines. The control signal controls the bias of the laser enabling the automatic tuning of the laser 102 to the desired output wavelength, which is substantially equal to the characteristic wavelength of the reference gas plus (minus) Δλ/2, and is occurs again when the error signal ε=0 (but ΔP 208 (see below) is constant). Beneficially, by adjusting the bias point with the control signal, the laser 102 is controlled to tune its output to be substantially equal to the characteristic wavelength of the reference gas plus (minus) Δλ/2.

In an embodiment, the feedback control circuit 426 is a Proportional Integral (PI) controller configured to receive and process the error signal ε indicating the difference between the wavelength of the output signal of the laser and the characteristic wavelength, and to output the control signal CS in response. The PI controller includes an amplifier (not shown) that receives and amplifies the error signal E, outputting amplified error signal. The PI controller further includes an integrating logic device (not shown) that performs an integration function on the amplified error signal over time to provide an integrated error signal, and an adder (not shown) that adds the amplified error signal and the integrated error signal to output the control signal used to adjust the. In an embodiment, the PI controller may be replaced by a PID controller that also includes differentiating logic. Of course, the feedback control circuit 426 may include other types of control circuits, such as an on-off controller or controllers using fuzzy logic, without departing from the scope of the present teachings.

Finally, the PIC 400 is illustratively fabricated using one of a variety of known semiconductor processing methods commonly used in photonics. Just by way of example, in accordance with a representative embodiment in which the core is silicon and the cladding is SiO₂, the PIC 400 may be formed by forming a first layer of SiO₂ on a silicon substrate (not shown). The first layer of SiO₂ is comparatively flat and has a thickness of approximately a few micrometers (μm). Next, a thin layer of Silicon is formed over the first layer of SiO₂, such as by deposition of silicon. This layer has a thickness of approximately 400 nm. Next, photoresist is added and the etching mask (not shown) is created. Thereafter, the silicon is partially removed using a known etching technique to form the core. After formation, the core is covered by a second layer of SiO₂ which is flattened to complete the waveguide structure of the PIC 400.

Beneficially, the PIC 400 provides superior stability compared to certain bulk optic solutions and can be manufactured at a comparatively low cost. Since the locking scheme does not involve any high-speed electronics, the control electronics can also be built at a comparatively low cost and with very low noise as needed.

While the invention has been illustrated and described in detail in the drawings and foregoing description, such illustration and description are to be considered illustrative or exemplary and not restrictive; the invention is not limited to the disclosed embodiments.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

1. An apparatus for providing two wavelengths (λ and λ+42) from a laser source that are locked to the same resonance, the apparatus comprising:
an optical splitter configured to receive an optical signal and to split an input optical signal to provide a first optical signal and a second optical signal;
an optical modulator disposed in a first arm of the apparatus and adapted to cause a wavelength shift (Δλ) in the first optical signal;
a polarization rotator connected to an output of the optical modulator and adapted to orthogonally rotate the polarization of the first optical signal relative to the first optical signal;
an optical coupler configured to receive an output optical signal from the first arm, and the second optical signal from a second arm of the apparatus and to provide a third optical signal and an output optical signal;
an optical resonator connected to the optical coupler and adapted to attenuate the third optical signal at a characteristic wavelength;
a polarization beamsplitter connected to an output of the optical resonator and adapted to direct light of the output of the optical resonator having a first polarization state to a first photodetector adapted to provide a first photocurrent, and direct light of the output of the optical resonator having a second polarization state to a second photodetector adapted to provide a second photocurrent, wherein a difference between the first and second photocurrents from the first and second photodetectors increase when a difference between the characteristic wavelength and the laser wavelength increases, or decrease when the difference between the characteristic wavelength decrease; and
a feedback control circuit configured to change properties of the laser to be locked until an error signal indicative of the difference between the characteristic wavelength and the wavelength of the laser is offset by approximately Δλ/2.

2. The apparatus of claim 1, wherein the first and second optical signals experience different attenuation depending on the laser wavelength, except when the first and second optical signals are positioned substantially symmetric with respect to the characteristic wavelength.

3. The apparatus as recited in claim 1, wherein the difference between the photocurrents decreases when the difference between characteristic wavelength and a wavelength of the optical signal increases.

4. The apparatus as recited in claim 3, further comprising an adder configured to receive the first photocurrent and the photocurrent, and to provide an error signal indicative of the difference between the wavelength of the first optical signal and the characteristic wavelength.

5. The apparatus as recited in claim 4, wherein the feedback control circuit further comprises a Proportional Integral (PI) controller configured to receive and process the error signal, and in response, to output a control signal to the laser.

6. The apparatus as recited in claim 5, wherein in response to the control signal, the laser wavelength is defined by the characteristic wavelength and wavelength shift Δλ/2.

7. The apparatus as recited in claim 6, wherein the PI controller comprises an amplifier that receives and amplifies the error signal and provides an amplified error signal.

8. The apparatus as recited in claim 7, the PI controller further comprising an integrating logic device that performs an integration function on the amplified error signal over time to provide an integrated error signal.

9. The apparatus as recited in claim 8, wherein the adder is a first adder, and the feedback control circuit further comprises a second an adder configured to add the amplified error signal and the integrated error signal to provide the control signal.

10. The apparatus of claim 1, wherein the properties of the laser are one of a bias, temperature, phase shift, or mechanical shift.

11. The apparatus of claim 1, wherein the optical resonator comprises a reference gas providing molecular or atomic absorption at approximately an optical wavelength of the laser.

12. The apparatus of claim 1, wherein the optical resonator comprises a ring resonator adapted to attenuate the first optical signal at approximately an optical wavelength of the laser.

13. A photonic integrated circuit (PIC) for locking a wavelength of a laser, the PIC comprising:
a substrate;
an optical splitter disposed over the substrate and configured to receive an optical signal and to split an input optical signal to provide a first optical signal and a second optical signal;
an optical modulator disposed over the substrate and disposed in a first arm of PIC and adapted to cause a wavelength shift (Δλ) in the first optical signal;
a polarization rotator disposed over the substrate and connected to an output of the optical modulator and adapted to rotate the polarization of the first optical signal by 90° relative to the first optical signal;
an optical coupler disposed over the substrate and configured to receive an output optical signal from the first arm, and the second optical signal from a second arm of the PIC and to provide a third optical signal and an output optical signal;
an optical resonator disposed over the substrate and connected to the optical coupler and adapted to attenuate the third optical signal at a characteristic wavelength;
a polarization beamsplitter disposed over the substrate and connected to an output of the optical resonator and adapted to direct light of the output of the optical resonator having a first polarization state to a first photodetector adapted to provide a first photocurrent, and direct light of the output of the optical resonator having a second polarization state to a second photodetector adapted to provide a second photocurrent, wherein a difference between photocurrents from the first and second photodetectors increase when a difference between the characteristic wavelength and the laser wavelength increases, or decrease when the difference between the characteristic wavelength decrease; and
a feedback control circuit disposed over the substrate and configured to change properties of the laser to be locked until an error signal indicative of the difference between the characteristic wavelength and the wavelength of the laser is offset by approximately Δλ/2.

14. The PIC of claim 12, wherein the optical resonator comprises a reference gas providing molecular or atomic absorption at approximately an optical wavelength of the laser.

15. The PIC of claim 12, wherein the optical resonator comprises a ring resonator adapted to attenuate the first optical signal at approximately an optical wavelength of the laser.

16. The PIC as recited in claim 13, wherein the difference between the photocurrents decreases when the difference between characteristic wavelength and a wavelength of the optical signal increases.

17. The PIC as recited in claim 16, further comprising an adder configured to receive the first photocurrent and the second photocurrent, and to provide an error signal indicative of the difference between the wavelength of the first optical signal and the characteristic wavelength.

18. The PIC as recited in claim 17, wherein the feedback control circuit further comprises a Proportional Integral (PI) controller configured to receive and process the error signal, and in response, to output a control signal to the laser.

19. The PIC as recited in claim 18, wherein in response to the control signal, the laser wavelength is defined by the characteristic wavelength and wavelength shift Δλ/2.

20. The PIC as recited in claim 19, wherein the PI controller comprises an amplifier that receives and amplifies the error signal and provides an amplified error signal.
